(19) United States
(12) Patent Application Publication
(10) Pub. No.: US 2026/0349044 A1
(43) Pub. Date: Nov. 5, 2026

(54) APPARATUS AND METHOD FOR DETECTING LOW VOLTAGE DEFECTS IN BATTERY CELL

(71) Applicant: SK On Co., Ltd., Seoul (KR)

(72) Inventors: Sang Jo MOON, Daejeon (KR); Young Bee KIM, Daejeon (KR); Yu Jin LEE, Daejeon (KR); Kyung Hee JEONG, Daejeon (KR); Hyun Seong CHOI, Daejeon (KR)

(21) Appl. No.: 19/661,693

(22) Filed: Apr. 29, 2026

(30) Foreign Application Priority Data
Apr. 30, 2025 (KR) 10-2025-0057633

(51) Int. Cl. G01R 31/3842; H01M 50/569

(52) U.S. Cl. CPC G01R 31/3842; H01M 50/569

(57) ABSTRACT

Proposed are an apparatus and method for detecting low-voltage defects of battery cells. The apparatus includes a vacuum nozzle for forming a vacuum inside the battery cell, a pressure support member for pressurizing and supporting at least a portion of the gas pocket unit of the battery cell, a measuring instrument for applying a voltage to the electrode assembly and measuring an internal current, and a controller for determining whether the battery cell has low-voltage defects by comparing the measured current value with a preset reference value. The method includes forming a vacuum inside an electrode pocket unit of the battery cell, applying a voltage to an electrode assembly of the battery cell and measuring a current inside the electrode assembly, and determining whether the low-voltage defect is present by comparing the measured current value with a preset reference value.

### CROSS REFERENCE TO RELATED APPLICATION

The present application claims priority to Korean Patent Application No. 10-2025-0057633, filed on Apr. 30, 2025, the entire contents of which are incorporated herein for all purposes by this reference.

### TECHNICAL FIELD

The present disclosure relates to an apparatus and a method for detecting a low-voltage defect of a battery cell.

### BACKGROUND

A battery manufacturing process for a secondary battery may include an electrode process, an assembly process, a formation process, and a pack process.

The assembly process performs processes of assembling a positive and negative electrode manufactured in the electrode process together with a separator into a cell shape to form an electrode assembly, accommodating the electrode assembly in a battery case, welding a lead tab to the electrode assembly, and injecting an electrolyte.

The secondary battery assembled through the assembly process has only the shape of a battery and is in a state in which it is unable to perform its function as a battery. Accordingly, the battery is activated by performing charging and discharging through the formation process, thereby imparting electrical characteristics to the battery.

In the secondary battery manufactured in this manner, inspections are performed to detect or screen for defects in the battery. Such battery defect detection or screening is mostly performed during the formation process. In the battery defect detection or screening in the formation process, an aging process, in which the batteries are left and stored for several days, is essentially included in order to increase the capability of discriminating factors that cause low-voltage defects.

### SUMMARY

According to an aspect of the present disclosure, provided are an apparatus and a method for detecting a low-voltage defect of a battery cell, which are capable of detecting the low-voltage defect of the battery cell at an early stage of a battery assembly process.

According to an aspect of the present disclosure, provided are an apparatus and a method for detecting a low-voltage defect of a battery cell, which are capable of improving detection capability for defects caused by internal defects of the battery cell.

An apparatus and a method for detecting a low-voltage defect of a battery cell according to an aspect of the present disclosure are widely applied to green technologies such as electric vehicles, battery charging stations, and other photovoltaic power generation and wind power generation using batteries.

An apparatus and a method for detecting a low-voltage defect of a battery cell according to an aspect of the present disclosure are applied to a manufacturing process of secondary batteries used in eco-friendly electric vehicles, hybrid vehicles, and the like for preventing climate change by suppressing air pollution and greenhouse gas emissions.

In an apparatus including an electrode assembly, an electrode pocket unit in which the electrode assembly is accommodated, and a gas pocket unit connected to the electrode pocket unit for detecting a low-voltage defect of a battery cell, the apparatus for detecting the low-voltage defect of the battery cell according to an aspect of the present disclosure includes a vacuum nozzle configured to form a vacuum inside the battery cell, a pressure support member configured to pressurize and support at least a portion of the gas pocket unit of the battery cell, a measuring instrument electrically connected to the electrode assembly of the battery cell and configured to apply a voltage to the electrode assembly and to measure an internal current, and a controller configured to determine whether the battery cell has the low-voltage defect by comparing the measured current value received from the measuring instrument with a preset reference value.

According to an exemplary embodiment, a vacuum of 50 Torr to 100 Torr may be formed inside the electrode pocket unit of the battery cell.

According to an exemplary embodiment, the measuring instrument may apply a voltage of 100 V to 300 V to the electrode assembly.

According to an exemplary embodiment, the apparatus may further include a forward-backward moving member configured to move the vacuum nozzle to be drawn into or withdrawn from the gas pocket unit, and an elevating moving member configured to move the pressure support member to be closer to or further away from the gas pocket unit.

According to an exemplary embodiment, the apparatus may further include a press block configured to pressurize an upper and lower surface of the electrode pocket unit of the battery cell and to induce interfacial contact with the electrode assembly.

According to an exemplary embodiment, the press block may further include a cooling plate configured to cool the electrode pocket unit of the battery cell.

A method for detecting a low-voltage defect of a battery cell according to an aspect of the present disclosure includes forming a vacuum inside an electrode pocket unit of the battery cell, applying a voltage to an electrode assembly of the battery cell and measuring a current inside the electrode assembly, and determining whether the low-voltage defect is present by comparing the measured current value with a preset reference value.

According to an exemplary embodiment, the step of forming the vacuum inside the electrode pocket unit of the battery cell may include inserting a vacuum nozzle into a gas pocket unit of the battery cell, pressurizing and supporting an inlet part of the gas pocket unit, into which the vacuum nozzle is inserted, by a pressure support member, and drawing air from an interior of the battery cell by the vacuum nozzle inserted into the gas pocket unit.

According to an exemplary embodiment, the step of forming the vacuum inside the battery cell may form a vacuum of 50 Torr to 100 Torr inside the electrode pocket unit of the battery cell.

According to an exemplary embodiment, the step of applying the voltage to the electrode assembly of the battery cell and measuring the current inside the electrode assembly may apply a voltage of 100 V to 300 V to the electrode assembly.

According to an exemplary embodiment, the step of forming the vacuum inside the battery cell may further include inducing interfacial contact with respect to the electrode assembly by pressurizing an upper and lower surface of the electrode pocket unit of the battery cell with a press block, and cooling the electrode pocket unit when pressurizing the upper and lower surface of the electrode pocket unit with the press block.

According to an exemplary embodiment, the step of determining whether the low-voltage defect is present by comparing the measured current value with the preset reference value may determine the battery cell as having the low-voltage defect when the measured current value exceeds the preset reference value.

The features and advantages of the present disclosure will become more apparent from the following detailed description with reference to the accompanying drawings.

The terms and words used in the present specification and the claims should not be construed as having ordinary or dictionary meanings, but should be interpreted as meanings and concepts consistent with the technical spirit of the present disclosure, on the basis of the principle that the inventor may appropriately define the concepts of terms in order to describe his or her invention in the best way.

According to an exemplary embodiment of the present disclosure, it is possible to detect a low-voltage defect of a battery cell at an early stage during a battery assembly process.

According to an exemplary embodiment of the present disclosure, it is possible to detect an intrinsic defect inside a battery cell caused by a separator pinhole, damage or the like at an early stage during a battery assembly process.

According to an exemplary embodiment of the present disclosure, it is possible to improve detection capability for defects caused by internal defects of a battery cell.

According to an exemplary embodiment of the present disclosure, it is possible to detect defects of a battery cell at an early stage before the battery cell is introduced into a formation process when the battery cell is manufactured.

### BRIEF DESCRIPTION OF THE DRAWINGS

FIG. 1 is a view illustrating a battery cell structure for describing an apparatus and a method for detecting a low-voltage defect of a battery cell according to an exemplary embodiment.

FIG. 2 is a view illustrating an apparatus for detecting a low-voltage defect of a battery cell according to an exemplary embodiment.

FIG. 3 is a view illustrating an operating state in which a vacuum is formed and a current is measured in an apparatus for detecting a low-voltage defect of a battery cell according to an exemplary embodiment.

FIG. 4 is a view illustrating an apparatus for detecting a low-voltage defect of a battery cell further including a press block and a cooling plate according to an exemplary embodiment.

FIG. 5 is a view illustrating a method for detecting a low-voltage defect of a battery cell according to an exemplary embodiment.

FIG. 6 is a view illustrating a step of forming a vacuum inside an electrode pocket unit of a battery cell in a method for detecting a low-voltage defect of a battery cell according to an exemplary embodiment.

FIG. 7 is a view further illustrating a step of forming a vacuum inside an electrode pocket unit of a battery cell in a method for detecting a low-voltage defect of a battery cell according to an exemplary embodiment.

### DETAILED DESCRIPTION

Hereinafter, the present disclosure will be described in detail (with reference to the accompanying drawings). However, this may be only illustrative, and the present disclosure is not limited to the specific exemplary embodiments described as examples.

The drawings may be displayed schematically or in an exaggerated manner for the purpose of explaining the exemplary embodiments.

In this document, expressions such as "include," "may include," "have," "may have," and the like may indicate the presence of a corresponding feature (e.g., numerical values, functions, operations, or parts as components) and may not preclude the presence of additional features.

Hereinafter, an exemplary embodiment of the present disclosure will be described in detail with reference to the accompanying drawings.

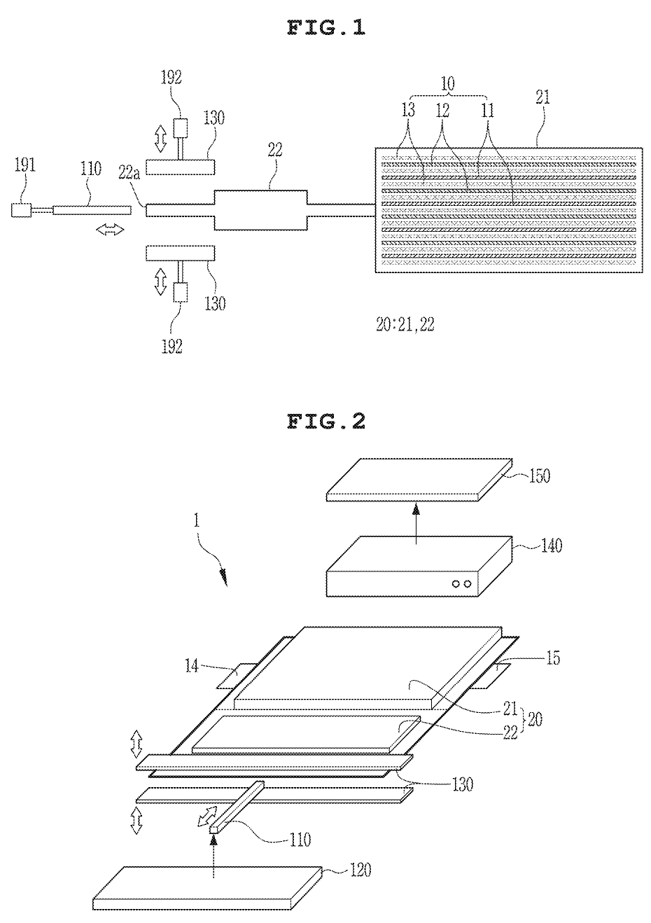

FIG. 1 is a view illustrating a battery cell structure for describing an apparatus and a method for detecting a low-voltage defect of a battery cell according to an exemplary embodiment.

Referring to FIG. 1, a battery cell 1 may be a product assembled in an assembly process of a battery manufacturing process. The battery cell 1 may be in a state in which an electrolyte is not injected among battery materials.

The battery cell 1 may include an electrode assembly 10 and a case 20 surrounding the electrode assembly 10. The case 20 may include an electrode pocket unit 21 in which the electrode assembly 10 is accommodated, and a gas pocket unit 22 connected to the electrode pocket unit 21.

The electrode assembly 10 may include a positive electrode 11, a negative electrode 12, and a separator 13. The separator 13 may be positioned between the positive electrode 11 and the negative electrode 12. The positive electrode 11, the negative electrode 12, and the separator 13 may have a structure in which a plurality thereof is stacked.

The case 20 may be made of a metal material or a plastic material. The case 20 may be a composite material in which metal and plastic are combined. The case 20 may be a pouch film. The pouch film may include an aluminum foil. The pouch film may be formed by laminating an aluminum foil, a polyethylene terephthalate (PET) film, a nylon film, and a cast polypropylene (CPP) film. The case 20 is not limited to these examples, and may be made of various other materials.

The gas pocket unit 22 connected to the electrode pocket unit 21 may be used for an electrolyte injection process in which an electrolyte is injected into the electrode pocket unit 21 and a degassing process in which unnecessary gas is discharged and collected from an interior of the electrode pocket unit 21. The gas pocket unit 22 may be cut and removed after the degassing process.

The apparatus and the method for detecting a low-voltage defect of a battery cell according to an exemplary embodiment may be performed in a state in which the battery cell 1 includes the electrode pocket unit 21 and the gas pocket unit 22. The apparatus and the method for detecting a low-voltage defect of a battery cell may be incorporated into the battery assembly process. The apparatus and the method for detecting a low-voltage defect of a battery cell may be performed before the electrolyte injection process in which an electrolyte is injected into the electrode pocket unit 21 of the battery cell 1 during the battery assembly process.

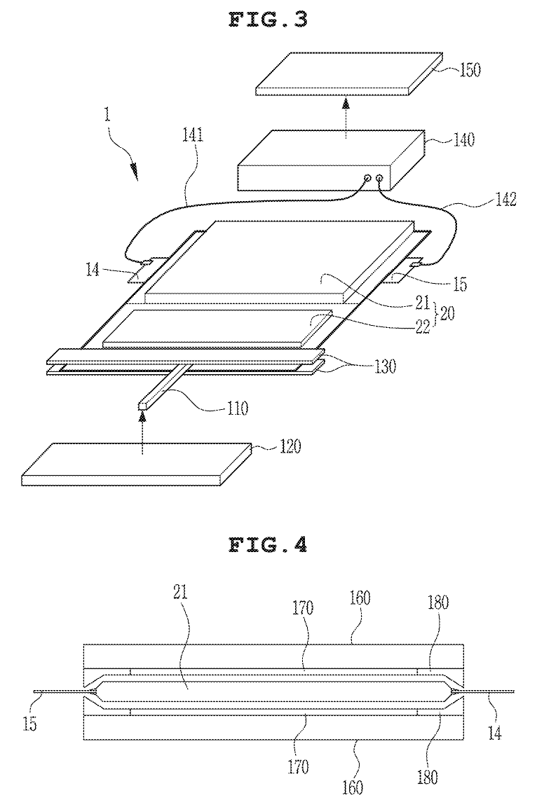

FIG. 2 is a view illustrating an apparatus for detecting a low-voltage defect of a battery cell according to an exemplary embodiment, and FIG. 3 is a view illustrating an operating state in which a vacuum is formed and a current is measured in an apparatus for detecting a low-voltage defect of a battery cell according to an exemplary embodiment. FIG. 1 is referred to together.

Referring to FIGS. 1 to 3, In an apparatus including an electrode assembly 10, an electrode pocket unit 21 in which the electrode assembly is accommodated, and a gas pocket unit 22 connected to the electrode pocket unit 21 for detecting a low-voltage defect of a battery cell, the apparatus for detecting a low-voltage defect of a battery cell according to one aspect of the present disclosure may include a vacuum nozzle configured to form a vacuum inside the battery cell 1, a pressure support member 130 configured to pressurize and support at least a portion of the gas pocket unit 22 of the battery cell 1, a measuring instrument 140 electrically connected to the electrode assembly 10 of the battery cell 1 and configured to apply a voltage to the electrode assembly 10 and to measure an internal current, and a controller 150 configured to determine whether the battery cell 1 has a low-voltage defect by comparing the measured current value received from the measuring instrument 140 with a preset reference value.

The vacuum nozzle 110 may have a structure having a through hollow. The vacuum nozzle 110 may be formed to have a size insertable into an inlet part 22a of the gas pocket unit 22 of the battery cell 1. The vacuum nozzle 110 may be installed to be insertable into and withdrawable from the gas pocket unit 22. As illustrated, the vacuum nozzle 110 may be positioned in front of the gas pocket unit 22. The vacuum nozzle 110 may be installed to be movable forward and backward. The vacuum nozzle 110 may be connected to a vacuum generator 120. The vacuum nozzle 110 and the vacuum generator 120 may be used to form a vacuum inside the battery cell 1. The vacuum may be formed inside the electrode pocket unit 21 of the battery cell 1. When the vacuum is formed inside the electrode pocket unit 21 of the battery cell 1, the electrode pocket unit 21 may be pressurized by atmospheric pressure, such that the electrode pocket unit 21 and the electrode assembly 10 accommodated therein may be brought into close contact with each other. In addition, interfacial contact between components of the electrode assembly 10 that is in close contact with the electrode pocket unit 21 may also be induced due to the action of atmospheric pressure under the vacuum condition. That is, interfacial contact between the positive electrode 11 and the separator 13 and between the negative electrode 12 and the separator 13 may be induced in the electrode assembly 10. Through such interfacial contact, contact resistance and an ion migration distance in the electrode assembly 10 may be reduced, and an electrical path may be easily formed, thereby making it easier to check whether a leakage current occurs.

The term "interfacial contact" used in the present disclosure may refer to close contact between a positive electrode 11 and a separator 13, and to close contact between a negative electrode 12 and the separator 13, in an electrode assembly 10. In addition, "interfacial contact" may include close contact between an electrode pocket unit 21 and the electrode assembly 10 accommodated therein.

The vacuum generator 120 may be a device that generates a vacuum using compressed air. The vacuum generator 120 may generate a vacuum by changing a flow velocity of the compressed air. The vacuum generator 120 may be connected to the vacuum nozzle 110 through a connection hose. The vacuum generator 120 may form a vacuum in the electrode pocket unit 21 through the vacuum nozzle 110. The vacuum nozzle 110 may draw air from an interior of the battery cell 1.

Through the vacuum nozzle 110 and the vacuum generator 120, a vacuum of 50 Torr to 100 Torr may be formed inside the electrode pocket unit 21 of the battery cell 1. In this case, when an excessive vacuum of less than 50 Torr is formed, a separator loosening defect may occur in which the bonding of the separator 13 positioned at an outermost side of the electrode assembly 10 is broken. For this reason, when a sealing process is performed with the separator 13 inserted, additional defects derived therefrom, such as insulation defects, may occur. In addition, a time required to form the vacuum may be relatively increased. Also, when the vacuum exceeds 100 Torr, interfacial contact in the electrode assembly 10 may not be smoothly achieved, and detection capability for a low-voltage defect may be degraded.

When the vacuum nozzle 110 is inserted into the gas pocket unit 22 of the battery cell 1 and a vacuum is formed inside the electrode pocket unit 21, the pressure support member 130 may provide a sealing force with respect to an inlet part 22a of the gas pocket unit 22 and simultaneously provide a stable fixing force with respect to the vacuum nozzle 110 inserted into the gas pocket unit 22. The pressure support member 130 may assist efficient vacuum formation by preventing external leakage of the vacuum supplied from the vacuum nozzle 110 to the electrode pocket unit 21 via the gas pocket unit 22. The pressure support member 130 may be installed to be movable toward or away from the gas pocket unit 22. As illustrated, the pressure support member 130 may be installed as a pair positioned above and below the gas pocket unit 22. The pressure support member 130 may be installed to be vertically movable.

The measuring instrument 140 may have a positive power line 141 electrically connected to a positive tab 14 of the battery cell 1 and have a negative power line 142 electrically connected to a negative tab 15 of the battery cell 1. The positive tab 14 may be coupled to the positive electrode 11 inside the electrode pocket unit 21, and a portion thereof may be exposed outside the electrode pocket unit 21. The negative tab 15 may be coupled to the negative electrode 12 inside the electrode pocket unit 21, and a portion thereof may be exposed outside the electrode pocket unit 21. The measuring instrument 140 may test the insulation performance of the battery cell 1 by applying a voltage to the battery cell 1 and measuring a current. The measuring instrument 140 may be a Hi-Pot (high potential) tester.

When a voltage is applied to the electrode assembly 10 of the battery cell 1 in the measuring instrument 140, a current flow may be formed inside the electrode assembly 10. The measuring instrument 140 may apply a voltage of 100 V to 300 V to the electrode assembly 10. Accordingly, the measuring instrument 140 may measure a current inside the electrode assembly 10. When the battery cell 1 is normal, an electrical path may be normally formed.

Conversely, when the battery cell 1 is defective, an electrical path may be abnormally formed when a voltage is applied. Leakage current may occur through a defective part of the battery cell 1. The current value measured through the measuring instrument 140 may increase.

At this time, interfacial contact between components of the electrode assembly 10 and between the electrode assembly 10 and the electrode pocket unit 21 may be induced by the vacuum formation in the electrode pocket unit 21 of the battery cell 1. In this way, by inducing interfacial contact in the electrode assembly 10 using the vacuum, defective parts having defect factors within the electrode assembly 10 may be more prominently exposed, and electrical paths at the interfaces may be more readily formed. For example, in the case of the battery cell 1 having a defect factor such as a pinhole in the separator 13, an abnormal electrical path may be generated through the pinhole of the separator 13. The positive electrode 11 and the negative electrode 12, which should be electrically insulated from each other, may come into electrical contact with each other through the pinhole in the separator 13. Due to interfacial contact between components of the electrode assembly 10 and between the electrode assembly 10 and the electrode pocket unit 21, a micro short circuit may be more easily induced. In addition, when damage occurs in the separator 13 due to the ingress of metallic foreign matter, an abnormal electrical path may be generated inside the battery cell 1 through a damaged part of the separator 13. Even in this case, a micro short circuit may be more readily induced due to interfacial contact between components of the electrode assembly 10 and between the electrode assembly 10 and the electrode pocket unit 21.

The controller 150 may compare the current value inside the electrode assembly 10 measured through the application of the voltage in the measuring instrument 140 with a preset reference value and may determine the battery cell as having a low-voltage defect when the measured current value inside the electrode assembly 10 exceeds the preset reference value.

Meanwhile, a short circuit inside a battery may occur during a manufacturing process when insulation is not properly maintained due to various factors. A soft short, which is a very fine short circuit such as a pinhole formed in a separator, may take a relatively longer time for a low-voltage defect to manifest as compared to a hard short. That is, defects may occur during use in the field after the battery is distributed.

In addition, foreign matter, including metallic particles, may be introduced into the battery. Such foreign matter introduced into the battery may cause damage to the separator and may result in a micro short circuit. In this case as well, manifestation of a low-voltage defect may take a relatively long time.

However, in the present disclosure, a vacuum may be formed in the electrode pocket unit 21 by using the gas pocket unit 22 that is necessarily included in the battery cell 1 during the battery assembly process. Accordingly, interfacial contact between components of the electrode assembly 10 and between the electrode assembly 10 and the electrode pocket unit 21 may be induced by atmospheric pressure under the vacuum condition. In addition, the current may be measured by applying a voltage to the electrode assembly 10 in a state where interfacial contact between components of the electrode assembly 10 and between the electrode assembly 10 and the electrode pocket unit 21 is induced by atmospheric pressure under the vacuum condition. That is, since the voltage is applied in a state in which interfacial contact of the electrode assembly 10 is induced, when a defective part exists within the electrode assembly 10, a micro short circuit may be more readily induced through the defective part. Accordingly, in the present disclosure, in the case of the battery cell 1 having defect factors such as separator pinholes or separator damage caused by the ingress of foreign matter, the low-voltage defect may be detected at an early stage during the battery assembly process. It is possible to improve the detection capability for micro defects caused by the defect factors of the battery cell 1. In addition, since the detection of the low-voltage defect of the battery cell 1 is performed during the battery assembly process in the present disclosure, additional advantages may be achieved in that an aging process and an open circuit voltage (OCV) measurement process conventionally performed in a subsequent battery formation process can be omitted. Through the present disclosure, it is possible to reduce the overall manufacturing process and time for battery production.

In addition, the apparatus for detecting a low-voltage defect of a battery cell according to the present disclosure may be introduced into and used in an existing battery manufacturing equipment line. For this purpose, the vacuum nozzle 110 and the pressure support member 130 may each be installed to allow movement control. To this end, the apparatus may further include a first moving member 191 configured to move the vacuum nozzle 110 to be drawn into or withdrawn from the gas pocket unit 22, and a second moving member 192 configured to move the pressure support member 130 toward or away from the gas pocket unit 22.

The first moving member 191 and the second moving member 192 may be driven by a cylinder driving method or a motor driving method. In FIG. 1, a cylinder driving method is illustrated as one example.

The controller 150 may determine whether the battery cell 1 has a low-voltage defect and may also control the driving of the first moving member 191 and the second moving member 192. The controller 150 may further control operations of the vacuum generator 120 and the measuring instrument 140.

FIG. 4 is a view illustrating an apparatus for detecting a low-voltage defect of a battery cell further including a press block and a cooling plate according to an exemplary embodiment.

Referring to FIG. 4, the apparatus for detecting a low-voltage defect of a battery cell according to the present disclosure may further include a press block 160 configured to pressurize upper and lower surfaces of the electrode pocket unit 21 of the battery cell 1 to induce the interfacial contact within the electrode pocket unit 21. The press block 160 may be installed in a pair structure in the upper and lower directions where the electrode pocket unit 21 of the battery cell 1 is positioned. The press block 160 may be a component of a press machine, which is a device whose drive in the upper and lower directions is controlled. The press block 160 may be controlled for movement in the upper and lower directions by the controller 150.

Through the press block 160, physical pressure may be applied to induce the interfacial contact in the electrode assembly 10 within the electrode pocket unit 21. Through this, contact resistance and an ion migration distance within the electrode assembly 10 may be further reduced when a voltage is applied, and the formation of an electrical path and the size of the leakage current in the electrode assembly 10 may be maximized.

In addition, the press block 160 may further include a cooling plate 170 for cooling the electrode pocket unit 21 of the battery cell 1. The cooling plate 170 may be installed to cool the entire region or the local region of the electrode pocket unit 21 of the battery cell 1. The cooling plate 170 may be disposed on the lower surface of the press block 160 in a protruding or non-protruding structure. The cooling plate 170 may have a cooling function in a variety of forms, including a structure in which a plurality of cooling coils through which refrigerants are circulated are accommodated. The entire region or the local region of the electrode pocket unit 21 of the battery cell 1 may be cooled through the cooling plate 170, and the electrode assembly 10 may be cooled by cooling energy transfer. Accordingly, the temperature of the electrode assembly 10 may be lowered, such that contact resistance in the electrode assembly 10 is reduced when the voltage is applied and the size of the leakage current may be maximized. That is, it is possible to increase detection capability for a low-voltage defect of the battery cell 1.

In addition, the apparatus for detecting a low-voltage defect of a battery cell according to the present disclosure may further include a silicone pad 180 for further expanding an interfacial contact region of the electrode assembly 10 by pressurizing an edge portion of the electrode pocket unit 21 of the battery cell 1. The silicone pad 180 may be disposed at an edge of the lower surface of the press block 160. The silicone pad 180 may have a shape structure corresponding to an edge portion of the electrode pocket unit 21.

Through the silicone pad 180, the interfacial contact may be extended to the edge region of the electrode assembly 10 by pressurizing the edge portion of the electrode pocket unit 21 of the battery cell 1. Accordingly, it is possible to reduce the contact resistance and an ion migration distance in the electrode assembly 10 when a voltage is applied, and to form an electrical path in the electrode assembly 10 and maximize the size of the leakage current.

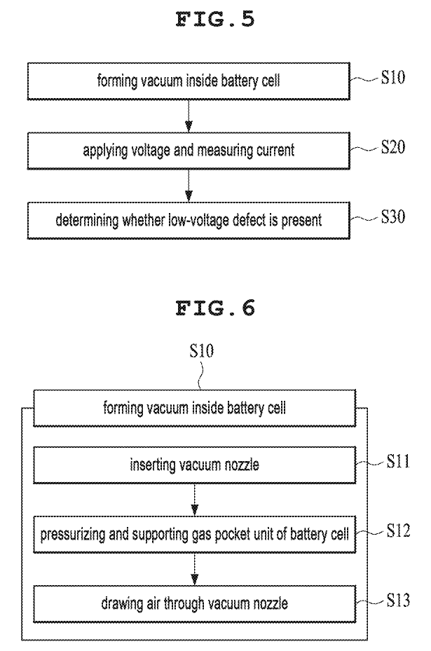

FIG. 5 is a view illustrating a method for detecting a low-voltage defect of a battery cell according to an exemplary embodiment, and FIG. 6 is a view illustrating a step of forming a vacuum inside an electrode pocket unit of a battery cell in a method for detecting a low-voltage defect of a battery cell according to an exemplary embodiment. FIGS. 1-3 are referred to together.

Referring to FIGS. 1 to 3 and 5, the method for detecting a low-voltage defect of a battery cell according to the present disclosure may include (S10) forming a vacuum inside the battery cell 1, (S20) applying a voltage to the electrode assembly 10 of the battery cell 1 and measuring the current inside the electrode assembly 10, and (S30) determining whether the low-voltage defect is present by comparing the measured current value with a preset reference value.

In the step (S10) of forming a vacuum inside the battery cell 1, a vacuum may be formed inside the electrode pocket unit 21 of the battery cell 1. Due to atmospheric pressure acting under the vacuum condition formed inside the battery cell 1, the interfacial contact may be induced between the components of the electrode assembly 10 and between the electrode assembly 10 and the electrode pocket unit 21.

In the step (S10) of forming a vacuum inside the battery cell 1, the vacuum nozzle 110 and the vacuum generator 120 may be used to form the vacuum.

In the step (S10) of forming a vacuum inside the battery cell, a vacuum of 50 Torr to 100 Torr may be formed inside the electrode pocket unit 21 of the battery cell 1. Through this, the interfacial contact may be induced not only between the positive electrode 11 and the separator 13 and between the negative electrode 12 and the separator 13 within the electrode assembly 10, but also between the electrode assembly 10 and the electrode pocket unit 21.

The step (S10) of forming a vacuum inside the battery cell 1 may include the following steps described below.

Referring to FIGS. 1 to 3 and 6, in the method for detecting a low-voltage defect of a battery cell according to the present disclosure, the step (S10) of forming a vacuum inside the battery cell 1 may include (S11) inserting the vacuum nozzle 110 into the gas pocket unit 22 of the battery cell 1, (S12) pressurizing and supporting the inlet part 22a of the gas pocket unit 22, into which the vacuum nozzle 110 is inserted, by the pressure support member 130, and (S13) drawing air from an interior of the battery cell 1 through the vacuum nozzle 110 inserted into the gas pocket unit 22.

In the step of inserting the vacuum nozzle 110 into the gas pocket unit 22 of the battery cell 1, the battery cell 1 assembled in the battery assembly process may be prepared. The battery cell 1 assembled in the battery assembly process may be introduced onto the manufacturing equipment line of the battery assembly process. The controller 150 may drive and control the first moving member 191 to move the vacuum nozzle 110. Through this, the vacuum nozzle 110 may be inserted into the gas pocket unit 22 of the battery cell 1.

In the step (S12) of pressurizing and supporting the inlet part 22a of the gas pocket unit 22, into which the vacuum nozzle 110 is inserted, by the pressure support member 130, the controller 150 may drive and control the second moving member 192 to move. The inlet part 22a of the gas pocket unit 22, into which the vacuum nozzle 110 is inserted, may be pressurized and supported by the pressure support member 130. Through this, the sealing force and fixing force may be provided to the inlet part 22a of the gas pocket unit 22.

In the step (S13) of drawing air from the interior of the battery cell 1 through the vacuum nozzle 110 inserted into the gas pocket unit 22, a vacuum may be formed inside the battery cell 1 by drawing air using the vacuum nozzle 110. The vacuum may be formed inside the electrode pocket unit 21 in which the electrode assembly 10 is accommodated. Through this, the interfacial contact may be induced not only between the positive electrode 11 and the separator 13 and between the negative electrode 12 and the separator 13 within the electrode assembly 10, but also between the electrode assembly 10 and the electrode pocket unit 21.

In the step (S20) of applying a voltage to the electrode assembly 10 of the battery cell 1 and measuring the current inside the electrode assembly 10, a voltage of 100V to 300V may be applied to the electrode assembly 10. The reason for limiting the value according to the voltage application may be to be used for current measurement regardless of the model of the battery cell 1 in consideration of mass-production specifications of an existing manufacturing equipment line. In particular, when less than 100V, the current measurement efficiency may decrease as a short-circuit induction rate within the electrode assembly 10 decreases. When exceeding 300V, it may cause damage to the battery cell 1 itself, such as damage to the separator. The controller 150 may apply a voltage to the electrode assembly 10 by controlling the operation of the measuring instrument 140. The measuring instrument 140 may measure the current inside the electrode assembly 10 and transmit the measured current value to the controller 150.

In the step (S20) of applying a voltage to the electrode assembly 10 of the battery cell 1 and measuring the current inside the electrode assembly 10, an electrical path may be normally formed when the battery cell 1 is normal. In contrast, when the battery cell 1 is defective due to a defect, an electrical path may be formed abnormally, and leakage current may occur through a defective part of the battery cell 1. Since the interfacial contact between components of the electrode assembly 10 is induced at the time the voltage is applied, a micro short circuit may be more readily induced at a defective part within the electrode assembly 10.

In the step (S30) of determining whether a low-voltage defect is present by comparing the measured current value with a preset reference value, the battery cell may be determined as having a low-voltage defect when the measured current value exceeds the preset reference value. When the battery cell 1 is determined to have a low-voltage defect, it may be determined that leakage current has occurred due to the occurrence of a defective part in the electrode assembly 10. Through this, it is possible to check an insulation state of the battery cell 1. In this case, the preset reference value may be an upper limit value of the current.

The step (S30) of determining whether a low-voltage defect is present by comparing the measured current value with a preset reference value may be performed by the controller 150 receiving the measured current value of the battery cell 1 from the measuring instrument 140.

The method for detecting a low-voltage defect of a battery cell according to the present disclosure may be performed before an electrolyte injection process in the battery assembly process. That is, the method for detecting a low-voltage defect of a battery cell may be performed during the battery assembly process.

Accordingly, through the method for detecting a low-voltage defect of a battery cell according to the present disclosure, in the case of a battery cell 1 having defect-inducing factors such as separator pinholes or separator damage caused by the ingress of foreign matter, the low-voltage defect may be detected at an early stage during the battery assembly process. Through this, it is possible to provide the additional effect of omitting the aging process and the open-circuit voltage (OCV) measurement process, which have been essentially performed in the battery formation process, which is a post-process of the battery assembly process. In addition, it is possible to shorten the overall process and time for battery manufacturing.

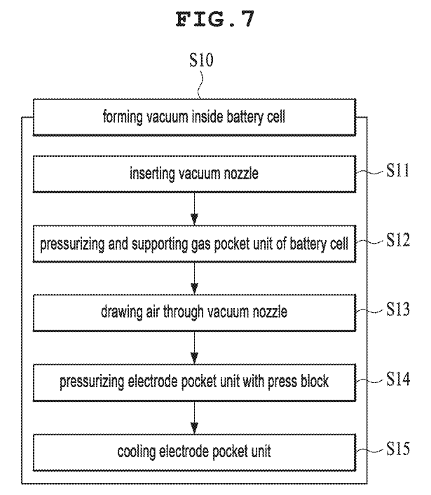

FIG. 7 is a view further illustrating a step of forming a vacuum inside an electrode pocket unit of a battery cell in a method for detecting a low-voltage defect of a battery cell according to an exemplary embodiment. FIGS. 1 and 4 are referred to together.

Referring to FIGS. 1, 4, and 7, in the method for detecting a low-voltage defect of a battery cell according to the present disclosure, the step (S10) of forming a vacuum inside the battery cell 1 may further include (S14) inducing the interfacial contact in the electrode assembly 10 by pressurizing the upper and lower surfaces of the electrode pocket unit 21 of the battery cell 1 with a press block 160, and (S15) cooling the electrode pocket unit 21 when pressurizing the upper and lower surfaces of the electrode pocket unit 21 with the press block 160.

In the step (S14) of inducing the interfacial contact in the electrode assembly 10 by pressurizing the upper and lower surfaces of the electrode pocket unit 21 of the battery cell 1 with the press block 160, the upper and lower surfaces of the electrode pocket unit 21 may be pressurized with the press block 160 in a state where the step (S13) of drawing air from the interior of the battery cell 1 by the vacuum nozzle 110 inserted into the gas pocket unit 22 is performed. Additional interfacial contact may be induced in the electrode assembly 10 of the battery cell 1. Through such additional interfacial contact, the contact resistance and an ion migration distance within the electrode assembly 10 may be reduced when a voltage is applied to the electrode assembly 10, and the formation of the electrical path in the electrode assembly 10 and the size of the leakage current may be maximized.

The controller 150 may control the driving of the press block 160 to pressurize the upper and lower surfaces of the electrode pocket unit 21 of the battery cell 1. Through this, additional interfacial contact may be induced in the electrode assembly 10.

In the step (S15) of cooling the electrode pocket unit 21 when pressurizing the upper and lower surfaces of the electrode pocket unit 21 with the press block 160, the entire region or the local region of the electrode pocket unit 21 may be cooled using the cooling plate 170. Through this, the cooling energy in the electrode pocket unit 21 may be transferred to the electrode assembly 10 to cool the electrode assembly 10. Accordingly, since the temperature of the electrode assembly 10 is lowered, the contact resistance in the electrode assembly 10 may be reduced when the voltage is applied and the size of the leakage current may be maximized. That is, it is possible to increase detection capability for a low-voltage defect of the battery cell 1.

The controller 150 may control the driving of the press block 160 to bring the cooling plate 170 into contact with the upper and lower surfaces of the electrode pocket unit 21 of the battery cell 1 for cooling.

Therefore, the apparatus and the method for detecting a low-voltage defect of a battery cell according to the present disclosure may be performed during the battery assembly process. Since a voltage is applied to the electrode assembly 10 in a state in which the interfacial contact of the electrode assembly 10 accommodated in the electrode pocket unit 21 of the battery cell 1 is induced, a micro short circuit at the defective part may be more easily induced in the case of the battery cell 1 having defect factors. It is possible to improve the detection capability for a low-voltage defect of the battery cell. It is possible to detect the low-voltage defect at an early stage during the battery assembly process rather than in the formation process.

The present disclosure has been described in detail through specific exemplary embodiments. The foregoing description is merely illustrative of principles of the present disclosure, and other components may be further included or substituted with other components within a range not departing from the scope of the present disclosure.

What is claimed is:

1. An apparatus for detecting a low-voltage defect of a battery cell including an electrode assembly, an electrode pocket unit in which the electrode assembly is accommodated, and a gas pocket unit connected to the electrode pocket unit, the apparatus comprising:
a vacuum nozzle configured to form a vacuum inside the battery cell;
a pressure support member configured to pressurize and support at least a portion of the gas pocket unit of the battery cell;
a measuring instrument electrically connected to the electrode assembly of the battery cell and configured to apply a voltage to the electrode assembly and to measure an internal current; and
a controller configured to determine whether the battery cell has the low-voltage defect by comparing the measured current value received from the measuring instrument with a preset reference value.

2. The apparatus of claim 1, wherein a vacuum of 50 Torr to 100 Torr is formed inside the electrode pocket unit of the battery cell.

3. The apparatus of claim 1, wherein the measuring instrument applies a voltage of 100 V to 300 V to the electrode assembly.

4. The apparatus of claim 1, further comprising:
a first moving member configured to move the vacuum nozzle to be drawn into or withdrawn from the gas pocket unit; and
a second moving member configured to move the pressure support member to be closer to or further away from the gas pocket unit.

5. The apparatus of claim 1, further comprising:
a press block configured to pressurize an upper and lower surface of the electrode pocket unit of the battery cell and to induce interfacial contact with the electrode assembly.

6. The apparatus of claim 5, wherein the press block further comprises a cooling plate configured to cool the electrode pocket unit of the battery cell.

7. A method for detecting a low-voltage defect of a battery cell, the method comprising:
forming a vacuum inside the battery cell;
applying a voltage to an electrode assembly of the battery cell and measuring a current inside the electrode assembly; and
determining whether the low-voltage defect is present by comparing the measured current value with a preset reference value.

8. The method of claim 7, wherein the step of forming the vacuum inside the battery cell comprises:
inserting a vacuum nozzle into a gas pocket unit of the battery cell;
pressurizing and supporting an inlet part of the gas pocket unit, into which the vacuum nozzle is inserted, by a pressure support member; and
drawing air from an interior of the battery cell by the vacuum nozzle inserted into the gas pocket unit.

9. The method of claim 7, wherein the step of forming the vacuum inside the battery cell forms a vacuum of 50 Torr to 100 Torr inside the electrode pocket unit of the battery cell.

10. The method of claim 7, wherein the step of applying the voltage to the electrode assembly of the battery cell and measuring the current inside the electrode assembly applies a voltage of 100 V to 300 V to the electrode assembly.

11. The method of claim 7, wherein the step of forming the vacuum inside the battery cell further comprises:
inducing an interfacial contact with respect to the electrode assembly by pressurizing an upper and lower surface of the electrode pocket unit of the battery cell with a press block; and
cooling the electrode pocket unit when pressurizing the upper and lower surface of the electrode pocket unit with the press block.

12. The method of claim 7, wherein the step of determining whether the low-voltage defect is present by comparing the measured current value with the preset reference value determines the battery cell as having the low-voltage defect when the measured current value exceeds the preset reference value.
